(19) United States
(12) Patent Application Publication
(10) Pub. No.: US 2025/0046620 A1
(43) Pub. Date: Feb. 6, 2025

(54) PLASMA PROCESSING METHOD

(71) Applicant: HITACHI HIGH-TECH CORPORATION, Minato-ku, Tokyo (JP)

(72) Inventors: Kenta NAKAJIMA, Tokyo (JP); Toru ITO, Tokyo (JP); Fumiyoshi OFUJI, Tokyo (JP)

(21) Appl. No.: 18/279,827

(22) PCT Filed: Apr. 26, 2022
(86) PCT No.: PCT/JP2022/018912

§ 371 Date: Aug. 31, 2023

(51) Int. Cl. H01L 21/3213; H01J 37/32; H01L 21/02; H01L 21/28; H01L 21/311; H01L 29/49; H01L 29/51; H10B 41/20; H10B 43/20

(52) U.S. Cl. CPC H01L 21/32136; H01J 37/32146; H01J 37/32174; H01L 21/02164; H01L 21/31116; H01L 29/40114; H01L 29/40117; H01L 29/495; H01L 29/517; H10B 41/20; H10B 43/20; H01J 37/32311; H01J 2237/332; H01J 2237/3341; H01J 2237/3347

(57) ABSTRACT

A plasma processing method for uniformly removing a processing target film in a lateral direction even when a depth of a trench is increased, in particular, a method for plasma-etching a tungsten film of a stacked film formed by alternately stacking an insulating film and the tungsten film. The method includes: a first depositing step of depositing a film; a first etching step of etching after the first depositing step; a second depositing step of depositing a film; a second etching step of etching using a mixed gas after the second depositing step; and a third etching step of etching after the second etching step, the second depositing step being performed after the first depositing step and the first etching step are repeated a predetermined number of times, and the second depositing step, the second etching step, and the third etching step are repeated a predetermined number of times.

### TECHNICAL FIELD

The present invention relates to a plasma processing method.

### BACKGROUND ART

In recent years, in a NAND flash memory technology, a NAND flash memory having a three-dimensional structure (3D-NAND) in which memory cells are stacked in a vertical direction becomes mainstream.

In a manufacturing process of the NAND flash memory having a three-dimensional structure, first, a process of forming, along a trench (an etching groove) formed perpendicular to a wafer surface, a stacked structure in which an insulating film which is a silicon oxide (SiO₂) film or the like and a metal film (a gate electrode film) which is a tungsten (W) film or the like each are alternately overlapped 100 or more layers, is performed.

Next, an etching process of uniformly removing, by performing isotropic etching using plasma, the plurality of tungsten films, which are stacked in a trench depth direction, in a lateral direction that is a direction parallel to the wafer surface is performed.

As a method for uniformly etching tungsten in such a trench in the lateral direction, PTL 1 discloses a two-step processing method in which tungsten at a groove bottom is removed by performing anisotropic etching and then tungsten on side surfaces is isotropically removed.

Specifically, in the anisotropic etching step, ions are perpendicularly incident on a sample to remove the tungsten at the groove bottom by generating plasma and applying radio frequency power to the sample. Regarding the isotropic etching, a method of generating plasma and performing processing without applying a radio frequency bias to a sample is disclosed.

### CITATION LIST

### Patent Literature

PTL 1: JP2019-176184A

### SUMMARY OF INVENTION

### Technical Problem

In a next-generation technology, higher integration is required, and it is necessary to handle a stacked structure in which the number of stacked layers is 200 layers or more and a depth of a trench is 12 μm or more. In the trench in such a stacked structure, a tungsten film is located at a position deeper than that in the trench in the related art. Therefore, it is difficult to achieve sufficient and uniform etching by the etching method disclosed in PTL 1.

Therefore, an object of the invention is to provide a plasma processing method capable of uniformly removing a film that is a processing target in a lateral direction even when a depth of a trench is increased.

### Solution to Problem

The invention provides a plasma processing method for plasma-etching a tungsten film of a stacked film formed by alternately stacking an insulating film and the tungsten film, the method includes: a first depositing step of depositing a deposited film; a first etching step of etching the tungsten film after the first depositing step; a second depositing step of depositing a deposited film; a second etching step of etching the tungsten film by using a mixed gas containing a Cl₂ gas, an N₂ gas, a CF₄ gas and a C₄F₈ gas after the second depositing step; and a third etching step of etching the tungsten film after the second etching step, the second depositing step is performed after the first depositing step and the first etching step are repeated a predetermined number of times, and the second depositing step, the second etching step, and the third etching step are repeated a predetermined number of times.

### Advantageous Effects of Invention

According to the invention, it is possible to uniformly remove a film that is a processing target in a lateral direction even when a depth of a trench is increased.

Problems, configurations, and effects other than those described above become obvious from the following description of embodiments.

### BRIEF DESCRIPTION OF DRAWINGS

FIG. 1 is a diagram illustrating a plasma processing apparatus according to an embodiment.

FIG. 2 is a flowchart of a plasma processing method in the related art.

FIGS. 3A and 3B are schematic diagrams illustrating stacked structures before processing and after the processing in a first cycle.

FIGS. 4A-4C are schematic diagrams illustrating a state where a second cycle in the related art is applied to a second stacked structure.

FIG. 5 is a diagram illustrating a relation between a depth of a trench and an etching amount in a plasma processing method in the related art.

FIG. 6 is a flowchart of a plasma processing method according to the embodiment.

FIGS. 7A-7C are schematic diagrams illustrating a state where a second cycle according to the embodiment is applied to the second stacked structure.

FIG. 8 is a diagram illustrating a relation between a depth of a trench and an etching amount in a plasma processing method according to the embodiment.

FIG. 9 is a diagram illustrating an etching amount difference when power of radio frequency power is changed from 0 W to 40 W.

FIG. 10 is a diagram illustrating an etching amount difference when an application time of the radio frequency power is changed from 3 s to 11 s.

FIG. 11 is a diagram illustrating a relation between the depth of the trench and the etching amount when the radio frequency power is time-modulated.

FIG. 12 is a diagram illustrating an etching amount difference when effective power of the radio frequency power is changed from 0 W to 60 W.

### DESCRIPTION OF EMBODIMENTS

Hereinafter, an embodiment of the invention will be described with reference to the drawings. The invention is not limited to the embodiment. Further, in the description of the drawings, the same parts are designated by the same reference numerals.

In order to facilitate understanding of the invention, a position, a size, a shape, a range, or the like of each component shown in the drawings may not represent an actual position, size, shape, range, or the like. Therefore, the invention is not necessarily limited to the position, size, shape, range, or the like illustrated in the drawings.

In the disclosure, each of directions indicated by an x axis, a y axis, and a z axis described in the drawings may be used to indicate a direction. Terms “upward” and “downward” may be referred to as a “z-axis plus direction” and a “z-axis minus direction”, and a horizontal direction may be referred to as an “x-axis direction”, a “y-axis direction”, and a “lateral direction”.

Further, a length in a z-axis direction is referred to as “height” or “depth”, and a length on a xy plane defined by an x-axis direction and the y-axis direction is referred to as “width”.

### <Description of Plasma Processing Apparatus>

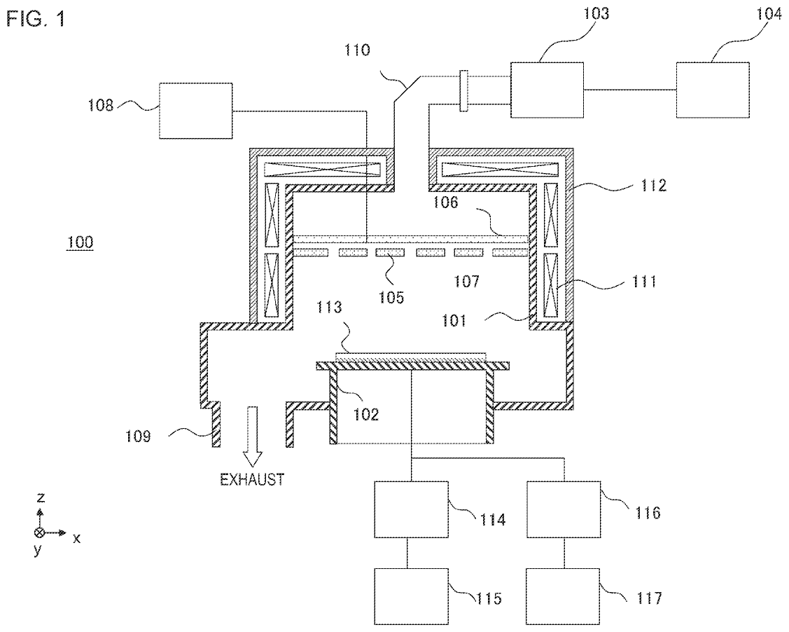

Hereinafter, a plasma processing apparatus according to an embodiment of the invention will be described with reference to FIG. 1. FIG. 1 is a diagram illustrating the plasma processing apparatus according to the present embodiment. In the present embodiment, an electron cyclotron resonance (ECR) microwave plasma etching apparatus is shown as an example of the plasma processing apparatus.

In a plasma processing apparatus 100, a shower plate 105 (for example, made of quartz) for introducing a processing gas into a vacuum container 101 and a dielectric window 106 (for example, made of quartz) are provided in the vacuum container 101. A sealed space below the dielectric window 106 forms a processing chamber 107. A plurality of holes for supplying the processing gas are disposed in the shower plate 105, and a gas supplied from a gas supply device 108 is introduced into the processing chamber 107 through the plurality of holes. In addition, a vacuum exhaust device (not shown) is connected to the vacuum container 101 via a vacuum exhaust port 109.

A waveguide 110 is provided above the dielectric window 106, and transmits an electromagnetic wave for generating plasma to the processing chamber 107. A radio frequency wave (a radio frequency wave for plasma generation) to be transmitted to the waveguide 110 is output from an oscillator 103 controlled by a first radio frequency power supply 104. Further, the first radio frequency power supply 104 includes a pulse oscillator, and can output a time-modulated intermittent radio frequency wave or a continuous radio frequency wave. A frequency of the radio frequency wave is not particularly limited, and in the present embodiment, a microwave of 2.45 GHZ (the radio frequency wave for plasma generation) is used.

A magnetic field generating coil 111 for generating a magnetic field is provided at an outer peripheral portion of the processing chamber 107. Plasma is generated in the processing chamber 107 by an interaction between the magnetic field generated by the magnetic field generating coil 111 and the electromagnetic wave introduced from the waveguide 110. The magnetic field generating coil 111 is covered by a coil case 112.

A sample stage 102 is provided at a position that faces the shower plate 105 and at a lower portion of the vacuum container 101. A surface of an electrode provided on the sample stage 102 is coated with a thermal sprayed film (not shown), and the electrode is connected to a direct current power supply 117 via a radio frequency filter 116. Further, a second radio frequency power supply 115, which is a radio frequency power supply for bias, is connected to the sample stage 102 via a matching circuit (a matching) device) 114. A temperature controller (not shown) is connected to the sample stage 102. A wafer 113 is conveyed into the processing chamber 107 of the vacuum container 101 by a conveying unit (not shown) and is placed on the sample stage 102.

The wafer 113 conveyed into the processing chamber 107 is adsorbed on the sample stage 102 by an electrostatic force caused by a direct current voltage applied from the direct current power supply 117, and a temperature of the wafer 113 is adjusted. After a desired processing gas is supplied into the processing chamber 107 by the gas supply device 108, the inside of the vacuum container 101 is controlled to a predetermined pressure via the vacuum exhaust device, and plasma is generated in the processing chamber 107 based on the radio frequency wave supplied from the oscillator 103. By applying radio frequency power (RF-bias) from the second radio frequency power supply 115 connected to the sample stage 102, ions are drawn from the plasma to the wafer 113, and the wafer 113 is plasma-processed (etched). Further, since the second radio frequency power supply 115 includes a pulse oscillator, it is possible to supply (apply) time-modulated intermittent radio frequency power or continuous radio frequency power to the sample stage 102.

### [Plasma Processing Method in the Related Art]

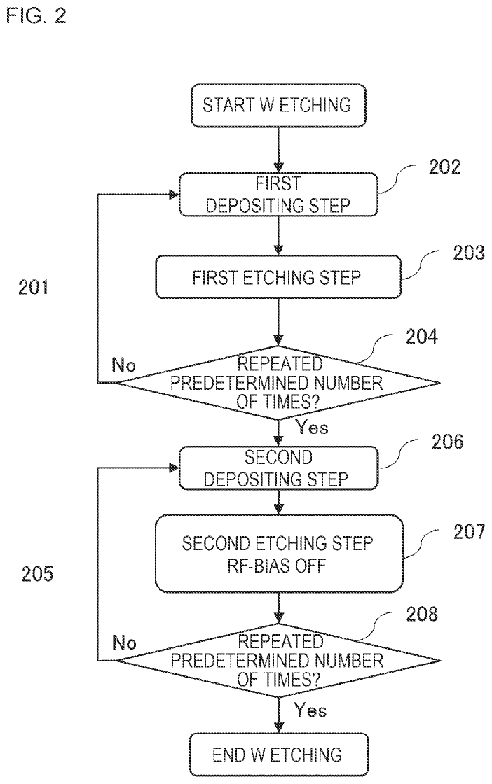

First, a case where a plasma processing method in the related art is applied will be described. FIG. 2 is a flowchart of the plasma processing method in the related art. A series of processing steps according to the plasma processing method includes a first cycle 201 to be applied to a stacked structure of a wafer in a predetermined processing stage (hereinafter, referred to as a “first stacked structure”), and a second cycle 205 to be applied to the stacked structure in a stage where the first cycle 201 is performed (hereinafter, referred to as a “second stacked structure”). Each cycle will be described below.

Table 1 shows conditions of each processing step in the flowchart illustrated in FIG. 2. In Table 1, items “Ar”, “He”, “CF₄”, “CHF₃”, “Cl₂”, “N₂”, “CH₂F₂”, and “C₄F₈” indicate types and flow rates of gases supplied by the gas supply device 108. An item “pressure” indicates a pressure value set in the vacuum container 101. An item “microwave” indicates power of the microwave (the radio frequency wave for plasma generation) output by the first radio frequency power supply 104 and transmitted through the waveguide 110. An item “RF-bias” indicates conditions (power (W), frequency (Hz), duty (%) of the radio frequency power applied from the second radio frequency power supply 115 to the wafer. An item “time” indicates a time (second(s)) during which the processing step is performed.

TABLE 1

| | | Ar | He | CF₄ | CHF₃ | Cl₂ | N₂ | CH₂F₂ | C₄F₈ |
|---|---|---|---|---|---|---|---|---|---|
| | | (ml/min) | | | | | | | |
| First | First depositing step | 290 | 290 | — | 10 | — | — | — | 12 |
| cycle | First etching step | 150 | 162 | 100 | — | 50 | 30 | — | 9 |
| Second | Second depositing step | 290 | 290 | — | 10 | — | — | 5 | 12 |
| cycle | Second etching step | 150 | 162 | 75 | — | 30 | 30 | — | 10 |
| | (RF-bias OFF) | | | | | | | | |

| | | | | RF-bias | | | |
|---|---|---|---|---|---|---|---|
| | | Pressure | Microwave | Power | Frequency | Duty | Time |
| | | (Pa) | (W) | (W) | (Hz) | (%) | (S) |
| First | First depositing | 6 | 400 | 100 | 1000 | 22 | 18 |
| cycle | step | | | | | | |
| | First etching | 5.9 | 700 | 0 | — | — | 58.5 |
| | step | | | | | | |
| Second | Second | 6 | 400 | 100 | 1000 | 22 | 15 |
| cycle | depositing step | | | | | | |
| | Second etching | 6.1 | 700 | 0 | — | — | 63.5 |
| | step (RF-bias | | | | | | |
| | OFF) | | | | | | |

### <First Cycle 201>

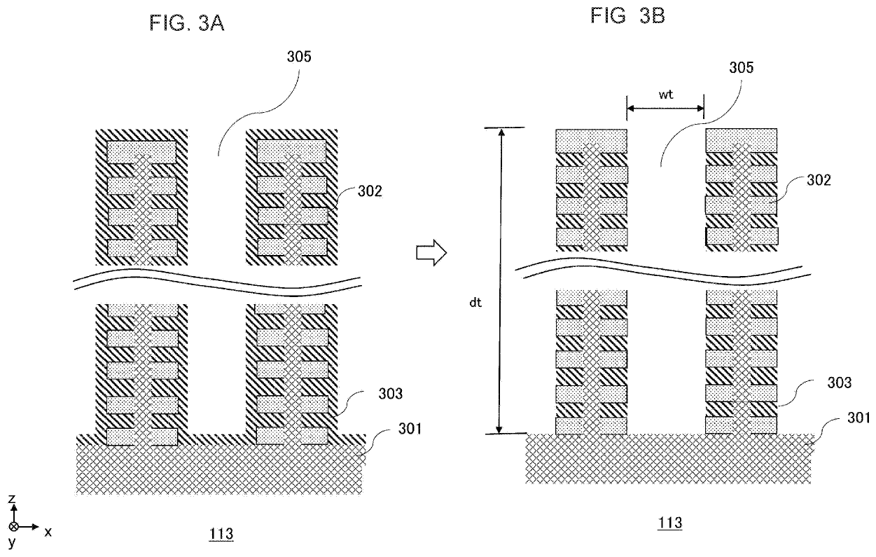

FIGS. 3A and 3B are schematic diagrams illustrating stacked structures before processing and after the processing in the first cycle 201.

Here, FIG. 3A shows the first stacked structure before the processing in the first cycle 201 is performed. The wafer 113 is a sample including a stacked film formed by alternately stacking an insulating film and a tungsten film. The wafer 113 includes a substrate made of polycrystalline silicon 301 and cores (channels) standing upright on the substrate. At least 200 layers of silicon oxide films 302 and at least 200 layers of tungsten films 303 are alternately stacked along the cores on the polycrystalline silicon 301, and further the tungsten films 303 also cover a surface of the wafer 113 so as to surround the layers of the silicon oxide films 302. A trench 305 that is a groove structure is formed on the wafer 113. The stacked structure is not limited to the silicon oxide films and the tungsten films as long as the stacked structure is a structure in which an insulating film and a metal film are alternately stacked along the trench.

FIG. 3B shows the second stacked structure when the processing in the first cycle 201 is performed. The first cycle 201 includes a first depositing step 202 of depositing a deposited film, and a first etching step 203 of etching the tungsten films in the stacked film after the first depositing step 202, and the first depositing step 202 and the first etching step 203 are repeated a predetermined number of times. For the tungsten films 303, a part surrounding the layers of the silicon oxide films 302 and covering the surface of the wafer 113 is removed, and the stacked structure is exposed along side walls of the trench 305.

In the present embodiment, when a depth of the trench 305 (a length from an uppermost portion to a lowermost portion of the stacked structure) is set to dt and a width is set to wt, it is also possible to set dt to 15.2 μm or more, and set wt to 134.5 nm or less. In addition, it is also possible to set dt to 11.7 μm or more and set wt to 160 nm or less. When an aspect ratio is set to dt/wt, the aspect ratio of the former is 113, and the aspect ratio of the latter is 73. A relation between the depth and the width of the trench 305 is not limited thereto. Further, the stacked structure shown in FIGS. 3A and 3B are not limited thereto.

When the total number of the tungsten films 303 is set to 344, from one tungsten film 303 at a deepest portion of the trench 305 (hereinafter, referred to as the “lowermost layer”), 1st to 10th layers are referred to as a Bottom portion (a B portion), 84th to 93rd layers are referred to as a Middle-Bottom portion (an MB portion), 168th to 177th layers are referred to as a Middle portion (a M portion), 251st to 260th layers are referred to as a Top-Middle portion (a TM portion), and 335th to 344th layers are referred to as a Top portion (a T portion) for the sake of convenience.

When a positional relation of each portion is expressed by a ratio of the number of accumulated layers counted from the lowermost layer to the total number of layers, the B portion corresponds to 0% to 3%, the MB portion corresponds to 24% to 27%, the M portion corresponds to 49% to 51%, the TM portion corresponds to 73% to 76%, and the T portion corresponds to 978 to 100%. As described above, when uniformity of the etching amount of the tungsten films 303 with respect to the depth of the trench 305 is evaluated, a value of the etching amount in predetermined layers (the B portion) including a layer corresponding to 0% (the lowermost layer) with the lowermost layer as a reference, a value of the etching amount in predetermined layers (the MB portion) including a layer corresponding to 25%, a value of the etching amount in predetermined layers (the M portion) including a layer corresponding to 508, a value of the etching amount in predetermined layers (the TM portion) including a layer corresponding to 75%, and a value of the etching amount in predetermined layers (the T portion) including a layer corresponding to 100% may be used (the predetermined layers includes, for example, 10 layers). However, the invention is not limited thereto, and the number of layers and the position of each portion and the number of the predetermined layers can be set as appropriate.

In the first depositing step 202, the supplied gases are, as shown in Table 1, an Ar gas at a supply rate of 290 ml/min, an He gas at a supply rate of 290 ml/min, a CHF₃ gas at a supply rate of 10 ml/min, and a C₄F₈ gas at a supply rate of 12 ml/min. The pressure in the vacuum container 101 is 6 Pa, the microwave for plasma generation is 400 W, the radio frequency power applied to the wafer is 100 W, 1000 Hz, 22%, and a time for the first depositing step 202 is 18 s.

In the first depositing step 202, a deposited film, which contains fluorocarbon containing CHₓF_{y} gas as a main component, is formed on an inner surface of the trench 305. The first depositing step 202 achieves an adjustment function of adjusting the balance between an amount of fluorine radicals, which serve as an etchant, and an amount of the deposited film, to make the etching progress at the same rate along a depth direction from the T portion to the B portion in the trench 305. In the following description, the deposited film containing fluorocarbon may be referred to as a protective film.

Similarly, in the first etching step 203, the supplied gases are an Ar gas at a supply rate of 150 ml/min, an He gas at a supply rate of 162 ml/min, a CF₄ gas at a supply rate of 100 ml/min, a Cl₂ gas at a supply rate of 50 ml/min, an N₂ gas at a supply rate of 30 ml/min, and a C₄F₈ gas at a supply rate of 9 ml/min. The pressure in the vacuum container 101 is 5.9 Pa, and the microwave for plasma generation is 700 W. No radio frequency power is applied to the wafer. A time for the first etching step 203 is 58.5 S.

In a repetition determination step 204, it is determined whether the first depositing step 202 and the first etching step 203 are repeated the predetermined number of times. When it is determined that the predetermined number of times is not reached, the process returns to the first depositing step 202. When it is determined that the predetermined number of times is reached, the first cycle 201 ends, and the process proceeds to a second depositing step 206 of the second cycle 205.

### <Second Cycle 205>

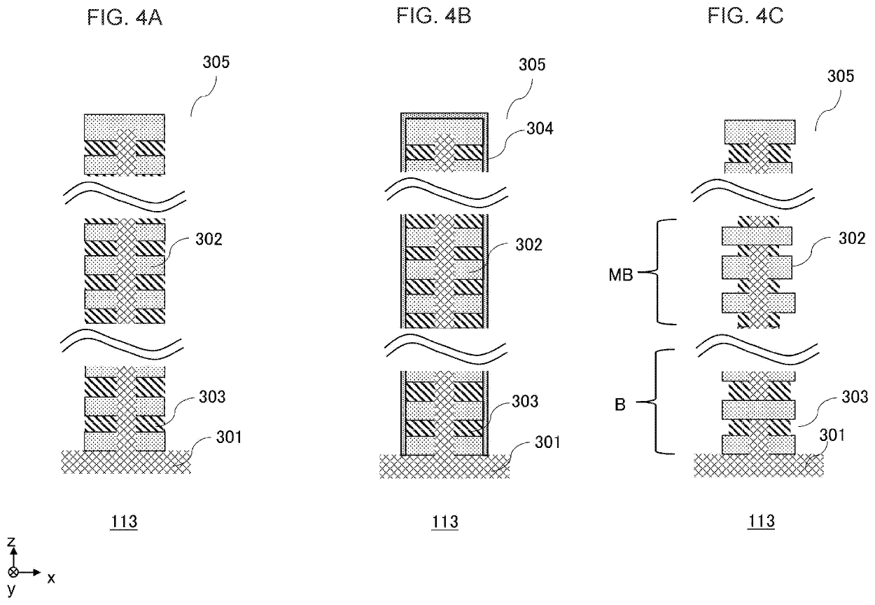

FIGS. 4A-4C are schematic diagrams illustrating a state where the second cycle 205 in the related art is applied to the second stacked structure.

Here, (FIG. 4A shows the second stacked structure when the first cycle 201 ends (see FIG. 3B).

In the second depositing step 206, the supplied gases are, as shown in Table 1, an Ar gas at a supply rate of 290 ml/min, an He gas at a supply rate of 290 ml/min, a CHF₃ gas at a supply rate of 10 ml/min, a CH₂F₂ gas at a supply rate of 5 ml/min, and a C₄F₈ gas at a supply rate of 12 ml/min. The conditions including the items “pressure”, “microwave”, and “RF-bias” are the same as the conditions for the first depositing step 202 of the first cycle 201. A time for the second depositing step 206 is 15 s.

FIG. 4B shows a state when the second depositing step 206 of the second cycle 205 is applied. By the second depositing step 206, a protective film 304, which contains fluorocarbon containing the CHₓF_{y} gas as a main component, is formed on surfaces of the silicon oxide films 302 and the tungsten films 303. The second depositing step 206 corresponds to the first depositing step 202 of the first cycle.

Similarly, in a second etching step (RF-bias OFF) 207 (hereinafter, also simply referred to as a “second etching step 207”), the supplied gases are an Ar gas at a supply rate of 150 ml/min, an He gas at a supply rate of 162 ml/min, a CF₄ gas at a supply rate of 75 ml/min, a Cl₂ gas at a supply rate of 30 ml/min, an N₂ gas at a supply rate of 30 ml/min, and a C₄F₈ gas at a supply rate of 10 ml/min. The pressure in the vacuum container 101 is 6.1 Pa, the microwave for plasma generation is 700 W, and no radio frequency power is applied to the wafer. A time for the second etching step 207 is 63.5 s.

A repetition determination step 208 is similar to the repetition determination step of the first cycle 201. FIG. 4C is a schematic diagram of the stacked structure when the second cycle 205 is performed four times in the order of the second depositing step 206 and the second etching step (RF-bias OFF) 207. As a result, the protective film 304 is removed, and the etching in a lateral direction of the tungsten films 303 progresses. However, as will be described later, there is a variation in the etching amount in the depth direction of the trench 305, and as a result, the etching amount at the MB portion is the largest and the etching amount at the B portion is the smallest.

### Results and Considerations

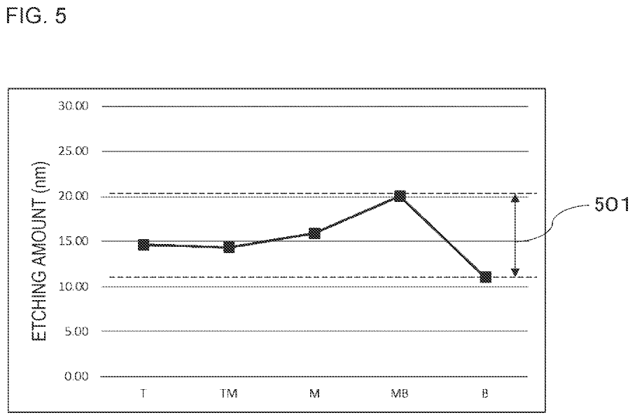

A result and a problem obtained by processing the stacked structure according to the plasma processing method in the related art described above will be described. FIG. 5 is a diagram illustrating a relation between the depth of the trench 305 and the etching amount in the plasma processing method in the related art. The etching amount of the tungsten films 303 at 5 locations, that is, the B portion, the MB portion, the M portion, the TM portion, and the T portion in the depth direction of the trench 305 has a maximum value of 20.01 nm at the MB portion and a minimum value of 11.03 nm at the B portion. A difference 501 between the maximum value and the minimum value of the etching amount in the trench depth direction (hereinafter, referred to as the “etching amount difference” unless otherwise specified) is 8.98 nm, which exceeds an allowable value of 4 nm. Here, the etching amount at each portion is displayed by using an average value of the 10 layers. As a criterion for evaluation, the allowable value of the etching amount difference is set to 4 nm or less. Note that 4 nm corresponds to about 3% of the width wt of the trench.

A reason why the value of the etching amount difference 501 is increased and a distribution of the etching amount deteriorates will be considered. In a structure in which the depth of the trench 305 is 12 μm or more, the etchant that contributes to the etching reaches the MB portion, but the etchant does not reach the B portion at a sufficient amount. As a result, it is considered that a recess amount at the B portion where the etching is hardly performed is smaller than that of other portions.

In addition, a reaction product generated when the etching progresses is moved upward in the trench 305 and reacts with the etchant. Since the etchant is consumed by such a reaction, it is considered that the progress of the etching is suppressed. From the T portion to the M portion, since the reaction product generated from a downward direction in the trench 305 is supplied, the progress of the etching may be appropriately suppressed, while in the MB portion, the etchant is small in amount in the lower B portion, the reaction product is also small in amount, and the supply of the reaction product to the MB portion is also small. Therefore, it is considered that the etching progresses excessively without being suppressed in the MB portion where the supply of the reaction product is small, and the etching amount difference between the MB portion and the B portion became worse.

### [Plasma Processing Method of the Present Embodiment]

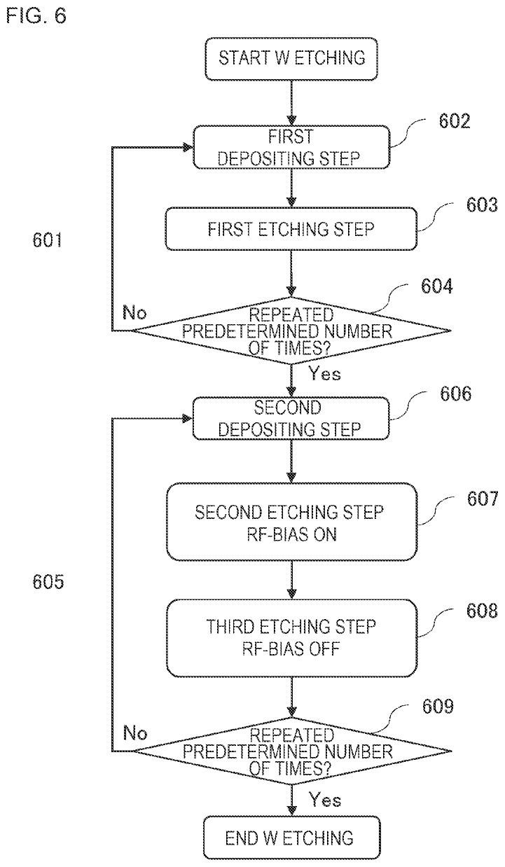

Next, a plasma processing method according to the present embodiment will be described. FIG. 6 is a flowchart of the plasma processing method according to the present embodiment. The plasma processing method according to the present embodiment is different from the plasma processing method in the related art described above in that a second etching step (RF-bias ON) 607 (hereinafter, also simply referred to as the “second etching step”) is provided in a second cycle 605. In other respects, the plasma processing method includes the same steps as those of the plasma processing method in the related art in FIG. 2. That is, a first depositing step 602, a first etching step 603, and a repetition determination step 604 of a first cycle 601 correspond to the first depositing step 202, the first etching step 203, and the repetition determination step 204 of the first cycle 201 of the plasma processing method in the related art shown in FIG. 2. Further, a second depositing step 606, a third etching step (RF-bias OFF) 608, and a repetition determination step 609 of the second cycle 605 correspond to the second depositing step 206, the second etching step (RF-bias OFF) 207, and the repetition determination step 208 of the second cycle 205 of the plasma processing method in the related art shown in FIG. 2. In the following description, the same or equivalent components as those of the plasma processing method in the related art described above are denoted by the same reference numerals, and the description thereof will be simplified or omitted.

Table 2 shows conditions for the second cycle 605 in the flowchart shown in FIG. 6. The second cycle 605 includes the second depositing step 606 of depositing a deposited film, the second etching step (RF-bias ON) 607 (hereinafter, also simply referred to as the “second etching step 607”) of etching the tungsten films by using a mixed gas containing a Cl₂ gas, an N₂ gas, a CF₄ gas, and a C₄F₈ gas after the second depositing step 606, and the third etching step (RF-bias OFF) 608 (hereinafter, also simply referred to as the “third etching step 608”) of etching the tungsten films after the second etching step 607, the second depositing step 606 is performed after the first cycle 601, and the second depositing step 606, the second etching step 607, and the third etching step 608 are repeated a predetermined number of times.

The second depositing step 606 is performed by using the C₄F₈ gas. The second depositing step 606 is performed under the same conditions as those for the second depositing step 206 of the second cycle 205 shown in FIG. 2.

TABLE 2

| | | Ar | He | CF₄ | CHF₃ | Cl₂ | N₂ | CH₂F₂ | C₄F₈ |
|---|---|---|---|---|---|---|---|---|---|
| | | (ml/min) | | | | | | | |
| Second | Second depositing step | 290 | 290 | — | 10 | — | — | 5 | 12 |
| cycle | Second etching step (RF- | 150 | 162 | 75 | — | 30 | 30 | — | 10 |
| | bias ON) | | | | | | | | |
| | Third etching step (RF- | 150 | 162 | 75 | — | 30 | 30 | — | 10 |
| | bias OFF) | | | | | | | | |

| | | | | RF-bias | | | |
|---|---|---|---|---|---|---|---|
| | | Pressure | Microwave | Power | Frequency | Duty | Time |
| | | (Pa) | (W) | (W) | (Hz) | (%) | (S) |
| Second | Second depositing step | 6 | 400 | 100 | 1000 | 22 | 15 |
| cycle | Second etching step (RF- | 6.1 | 700 | 20 | — | — | 5 |
| | bias ON) | | | | | | |
| | Third etching step (RF- | 6.1 | 700 | 0 | — | — | 58.5 |
| | bias OFF) | | | | | | |

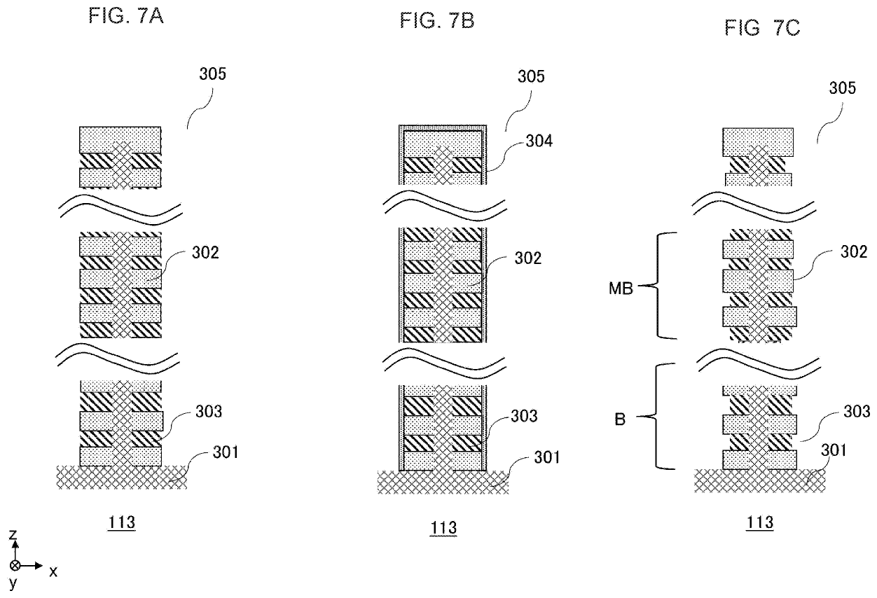

FIGS. 7A-7C are schematic diagrams illustrating a state where the second cycle 605 according to the present embodiment is applied to the second stacked structure. Since FIG. 7A and FIG. 7B are similar to FIG. 4A and FIG. 4B, the description thereof will be omitted. Further, FIG. 7C is a schematic diagram of the stacked structure when the second cycle 605 is performed a predetermined number of times in the order of the second depositing step 606, the second etching step (RE-bias ON) 607, and the third etching step (RF-bias OFF) 608. In the present embodiment, as shown in FIG. 7C, the variation in the etching amount at the MB portion and the B portion is suppressed.

The second etching step (RF-bias ON) 607 is a step of etching the tungsten films by using the mixed gas containing a Cl₂ gas, an N₂ gas, a CF₄ gas, and a C₄F₈ gas. Further, the second etching step (RE-bias ON) 607 is performed while the radio frequency power is supplied to the sample stage 102 on which the sample having the stacked film is placed. As shown in Table 2, in the second etching step (RF-bias ON) 607, the supplied gases are an Ar gas at a supply rate of 150 ml/min, an He gas at a supply rate of 162 ml/min, a CF₄ gas at a supply rate of 75 ml/min, a Cl₂ gas at a supply rate of 30 ml/min, an N₂ gas at a supply rate of 30 ml/min, and a C₄F₈ gas at a supply rate of 10 ml/min. The pressure in the vacuum container 101 is 6.1 Pa, the microwave for plasma generation is 700 W, the radio frequency power (RF-bias) applied to the wafer is 20 W, and an application time is 5 s.

The third etching step (RF-bias OFF) 608 is a step of etching the tungsten films after the second etching step (RF-bias ON) 607, and is performed by using the mixed gas containing a Cl₂ gas, an N₂ gas, a CF₄ gas, and a C₄F₈ gas. Further, the third etching step (RF-bias OFF) 608 is performed without supplying the radio frequency power to the sample stage 102. In the third etching step (RF-bias OFF) 608, the conditions, that is, the supplied gases, the pressure, and the microwave are the same as those of the second etching step (RF-bias ON) 607 except that a step time is 58.5 s and no radio frequency power (RF-bias) is applied to the wafer.

Although the mixed gas containing the gases shown in Table 2 is shown as a gas containing fluorine used for the second etching step (RF-bias ON) 607 and the third etching step (RF-bias OFF) 608, the invention is not limited thereto. As the gas containing fluorine, a mixed gas containing at least one of an NF₃ gas and an SF₆ gas may be used. Further, an Ar gas and an He gas have a function of a dilution gas.

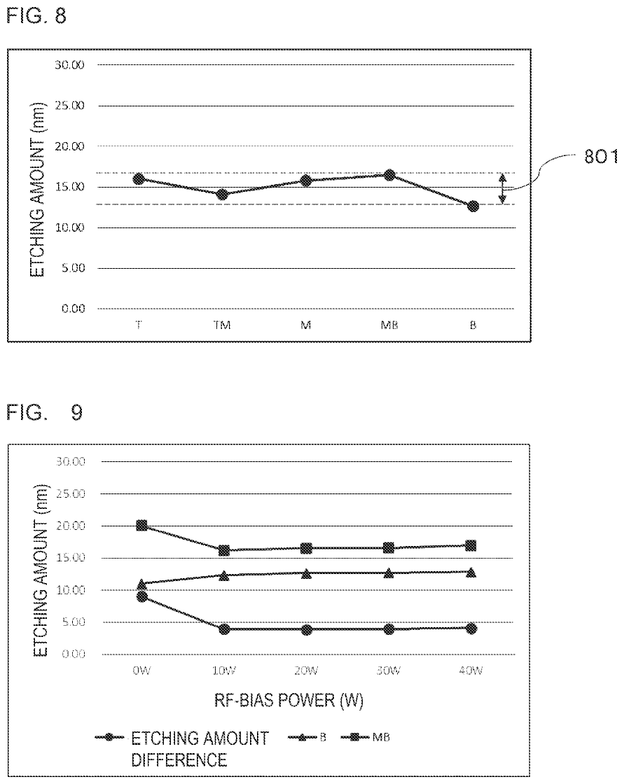

FIG. 8 is a diagram illustrating a relation between the depth of the trench and the etching amount in the plasma processing method according to the present embodiment. The etching amount has a maximum value of 16.52 nm at the MB portion and a minimum value of 12.63 nm at the B portion. An etching amount difference 801 in the trench depth direction is 3.89 nm, and the distribution of the etching amount is improved.

### Operations and Effects

It is considered that by providing the second etching step (RF-bias ON) 607 and appropriately applying the RF-bias (the radio frequency power) to the wafer, the ions are drawn into the trench 305 and a flow of the ions draws the etchant in the MB portion into the B portion. As a result, it is considered that the excessive etching amount at the MB portion is suppressed, while the etching amount at the B portion is increased, and the etching amount difference in the trench depth direction is reduced.

However, the application of the radio frequency power in the second etching step (RF-bias ON) 607 may excessively accelerate the etching of the protective film 304 containing fluorocarbon that adheres to the surface of the sample in the second depositing step 606, and may cause the etching on and damage the silicon oxide films 302 located on the surfaces of the stacked structure. Therefore, dependence of the power of the preferably usable radio frequency power and dependence of the application time was examined.

### [Dependence of Power of Radio Frequency Power]

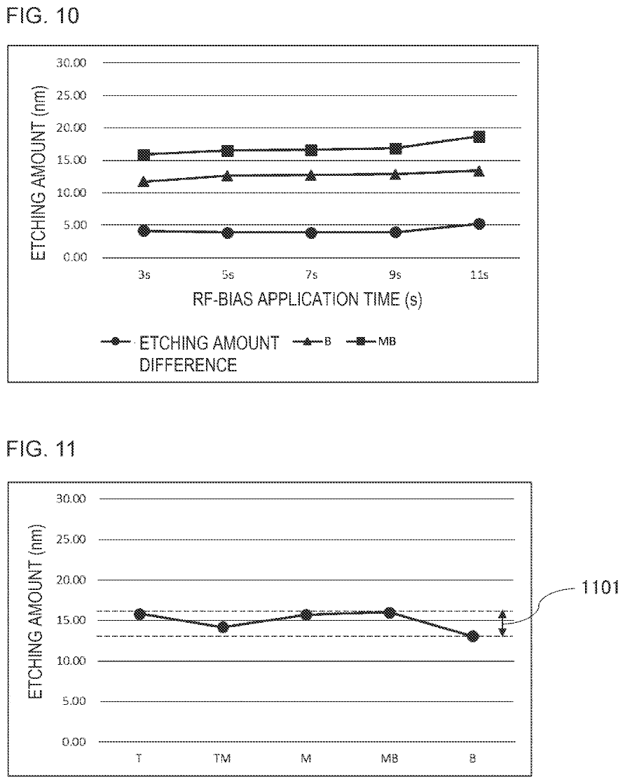

First, the dependence of power of the radio frequency power was examined. Among the conditions in Table 2, the power of the radio frequency power in the second etching step (RF-bias ON) 607 was changed from 0 W to 40 W, and the plasma process was performed. FIG. 9 is a diagram illustrating the etching amount difference when the power of the radio frequency power was changed from 0 W to 40 W. Here, since the maximum value of the etching amount appears in the MB portion and the minimum value appears in the B portion from the T portion to the B portion, the MB portion and the B portion were selected as representative places for observing the dependence of power of the etching amount in FIG. 9. The power of the radio frequency power was changed to 0 W, 10 W, 20 W, 30 W, and 40 W, and the distribution of the etching amount was measured. As a result, the etching amount difference in the trench depth direction had a maximum value of 8.99 nm when the radio frequency power was 0 W. When the radio frequency power was increased from 0 W to 20 W, the etching amount difference was decreased, and when the radio frequency power was 20 W, the etching amount difference had a minimum value of 3.89 nm. When the radio frequency power was increased from 20 W to 40 W, the etching amount difference was increased, and when the radio frequency power was 40 W, the etching amount difference was 4.11 nm. From the above, it was found that the etching amount difference in the trench depth direction was 4 nm or less when the power of the radio frequency power was in a range of 10 W to 30 W, and the distribution of the etching amount was good. Further, it was confirmed that when the power of the radio frequency power was 40 W, the surface of the stacked structure was damaged. From the above, it was found that it is not desirable to use the power of 40 W or more for the radio frequency power. Accordingly, it is desirable to set the power of the radio frequency power in a range of 10 W to 30 W when the radio frequency power is applied for 5 s. When the radio frequency power is defined by an amount of power, it is also possible to say that the desirable radio frequency power is in a range of 50 W/s to 150 W/s.

### [Dependence of Application Time of Radio Frequency Power]

Next, the dependence of the application time of the radio frequency power was examined. Among the conditions in Table 2, the application time of the radio frequency power in the second etching step (RF-bias ON) 607 was changed from 3 s to 11 s, and the plasma process was performed. FIG. 10 is a diagram illustrating the etching amount difference when the application time of the radio frequency power is changed from 3 s to 11 s. Here, in the second cycle 605, the application time of the radio frequency power was changed to 3 s, 5 s, 7 s, 9 s, 11 s while keeping a total time of the second etching step (RF-bias ON) 607 and the third etching step (RF-bias OFF) 608 constant, and an experiment was conducted. For example, in a case where the total time was set to 63.5 s, the application time for step 608 was 60.5 S when the application time for step 607 was 3 s, the application time for step 608 was 58.5 s when the application time for step 607 was 5 s, the application time for step 608 was 56.5 s when the application time for step 607 was 7 s, the application time for step 608 was 54.5 s when the application time for step 607 was 9 s, and the application time for step 608 was 52.5 s when the application time for step 607 was 11 s. However, the total time is not limited to this value. This is because when a ratio of the time for the etching step in which the radio frequency power supply is turned ON (step 607) and is turned OFF (step 608) to the time for the second depositing step 606 is changed, the etching amount is also affected, and thus the total time of the etching step is kept constant, and the influence caused by the change in the application time of the radio frequency power supply is better grasped.

When the application time of the radio frequency power was changed from 3 s to 5 s, the etching amount difference in the trench depth direction was decreased from 4.17 nm to 3.89 nm which is the minimum value. When the application time is increased from 5 s to 11 s, the etching amount difference increases, and a maximum value of 5.25 nm is obtained in the case of 11 s. When the application time of the radio frequency power was changed from 5 s to 9 s, the etching amount difference in the trench depth direction was 4 nm or less. From the above, it was found that when the radio frequency power was applied at 20 W, the application time was desirably in the range of 5 s to 9 s. When the radio frequency power is expressed by the amount of power, it is also possible to say that the desirable radio frequency power is in a range of 100 W/s to 180 W/s.

### Operations and Effects

In the experiments for the dependence of the power of the radio frequency power and the dependence of the application time, when the power was increased beyond the appropriate range of the radio frequency power and the application time was increased, the etching amount difference in the trench depth direction deteriorated. Considering a reason for the deterioration, when each of the output and the application time of the radio frequency power is within the appropriate range, an effect of drawing the etchant in the MB portion into the B portion is achieved. However, when the appropriate range is exceeded, a phenomenon also occurs in which the etchant existing between the T portion and the M portion is drawn into the MB portion. Therefore, an amount of the etchant in the MB portion increases, the etching progress more easily in the MB portion than in the B portion, and as a result, the etching amount difference is considered to be deteriorated.

### [Time Modulation of Radio Frequency Power]

In order to further improve the distribution of the etching amount, time modulation (TM) of the microwave and the radio frequency power was attempted. The TM of the microwave and the radio frequency power is to use a time-modulated intermittent radio frequency power for the microwave and the radio frequency power. When an ON time (a time of output) of the time-modulated intermittent radio frequency power is set to T_{ON} and an OFF time (a time with no output) is set to Torr, it is defined that the duty=T_{ON}/(T_{ON}+T_{OFF}). Conditions for the TM of the microwave and the radio frequency power were set such that the microwave for the second etching step (RF-bias ON) 607 and the third etching step (RF-bias OFF) 608 was set to 700 W, the frequency was set to 1000 Hz, the duty was set to 90%, the frequency of the radio frequency power for the second etching step (RF-bias ON) 607 was set to 1000 Hz, the duty was set to 30% and effective power was set to 20 W. The effective power is a product of the power and the duty. Detailed conditions for the second cycle 605 at that time are shown in Table 3.

TABLE 3

| | | Ar | He | CF₄ | CHF₃ | Cl₂ | N₂ | CH₂F₂ | C₄F₈ |
|---|---|---|---|---|---|---|---|---|---|
| | | (ml/min) | | | | | | | |
| Second | Second depositing step | 290 | 290 | — | 10 | — | — | 5 | 12 |
| cycle | Second etching step (RF-bias ON) | 150 | 162 | 75 | — | 30 | 30 | — | 10 |
| | Third etching step (RF-bias OFF) | 150 | 162 | 75 | — | 30 | 30 | — | 10 |

| | | | Microwave | | | RF-bias | | | |
|---|---|---|---|---|---|---|---|---|---|
| | | Pressure | Power | Frequency | Duty | Power | Frequency | Duty | Time |
| | | (Pa) | (W) | (Hz) | (%) | (W) | (Hz) | (%) | (S) |
| Second | Second | 6 | 400 | — | — | 100 | 1000 | 22 | 15 |
| cycle | depositing step | | | | | | | | |
| | Second | 6.1 | 700 | 1000 | 90 | 66.7 | 1000 | 30 | 5 |
| | etching step | | | | | | | | |
| | (RF-bias ON) | | | | | | | | |
| | Third etching | 6.1 | 700 | 1000 | 90 | 0 | — | — | 58.5 |
| | step (RF-bias | | | | | | | | |
| | OFF) | | | | | | | | |

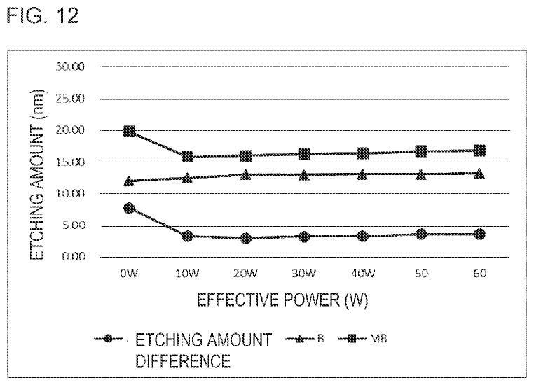

FIG. 11 is a diagram illustrating a relation between the depth of the trench and the etching amount when the radio frequency power is time-modulated. The etching amount has a maximum value of 16.03 nm at the MB portion and a minimum value of 13.06 nm at the B portion, and an etching amount difference 1101 in the trench depth direction is 2.97 nm, which is improved.

### Operations and Effects

During a time when the microwave is OFF, the CF₄ gas and the like that supply the etchant are dispersed in the trench 305. When the microwave is turned ON in this state, the etchant is dispersed and reacted in the trench 305 as compared with a case where the microwave is not time-modulated. As a result, it is considered that the etching amount difference in the trench depth direction is improved.

### [Dependence of Effective Power of Radio Frequency Power]

Next, dependence of the effective power and the distribution of the etching amount were examined in the state where the microwave and the radio frequency power were time-modulated. Among the conditions shown in Table 3, the duty of the radio frequency power was set to 30% such that the effective power in the second etching step (RF-bias ON) 607 was changed from about 0 W to about 60 W, then the plasma process was performed while the power of the radio frequency power was changed to 0 W (the effective power of 0 W), 33.3 W (the effective power of 10 W), 66.7 W (the effective power of 20 W), 100 W (the effective power of 30 W), 133.3 W (the effective power of 40 W), 166.7 W (the effective power of 50 W), and 200 W (the effective power of 60 W). FIG. 12 is a diagram illustrating the etching amount difference when the effective power of the radio frequency power is changed from 0 W to 60 W. The etching amount difference in the trench depth direction when the effective power was 0 W was showed to have a maximum value of 7.81 nm. When the effective power was increased from 0 W to 20 W, the etching amount difference was decreased, and the etching amount difference was 2.97 nm when the effective power was 20 W. When the effective power was increased from 20 W to 60 W, the etching amount difference was increased, and the etching amount difference was 4.02 nm when the effective power was 60 W. In addition, no damage on the surface of the stacked structure was confirmed up to when the effective power was 60 W. As described above, a good etching amount difference was obtained when the power was in the range of 10 W to 30 W from the viewpoint of the dependence of the power of the radio frequency power, but the range was expanded to a range of 10 W to 50 W from the viewpoint of the dependence of effective power of the radio frequency power.

### Operations and Effects

As a reason why the preferable effective power range was obtained, the dispersion of the gases for supplying the etchant when the microwave is turned OFF can be considered, as described in the time modulation of the radio frequency power. Further, as a reason why the range of the effective power in which no damage on the surface of the stacked structure occurs was widened, it is considered that the etching amount from an upper side of the protective film 304 and the silicon oxide films 302 on the surface of the stacked structure can be reduced by setting a time during which the microwave and the radio frequency power are turned off. From the above, it was found that it is desirable to set the effective power in the range of 10 W to 50 W when the power of the microwave is set to 700 W, the frequency is set to 1000 Hz, and the duty is set to 90%, and the frequency of the radio frequency power is set to 1000 Hz and the duty is set to 30%.

The embodiment of the invention is described above, but the invention is not limited to the embodiment described above, and various modifications can be made without departing from the scope of the invention.

For example, the preferable ranges of the power, the application time, the effective power, and the like of the radio frequency power supply can be appropriately adjusted and determined according to the desirable etching amount difference in the trench depth direction.

### REFERENCE SIGNS LIST

100 plasma processing apparatus
101 vacuum container
102 sample stage
103 oscillator
104 first radio frequency power supply
105 shower plate
106 dielectric window
107 processing chamber
108 gas supply device
109 vacuum exhaust port
110 waveguide
111 magnetic field generating coil
112 coil case
113 wafer
114 matching circuit
115 second radio frequency power supply
116 radio frequency filter
117 direct current power supply
201 first cycle
202 first depositing step
203 first etching step
204 repetition determination step
205 second cycle
206 second depositing step
207 second etching step (RF-bias OFF)
208 repetition determination step
301 polycrystalline silicon
302 silicon oxide film
303 tungsten film
304 protective film
305 trench
501, 801, 1101 etching amount difference
601 first cycle
602 first depositing step
603 first etching step
604 repetition determination step
605 second cycle
606 second depositing step
607 second etching step (RF-bias ON)
608 third etching step (RF-bias OFF)
609 repetition determination step

1. A plasma processing method for plasma-etching a tungsten film of a stacked film formed by alternately stacking an insulating film and the tungsten film, the plasma processing method comprising:
a first depositing step of depositing a deposited film;
a first etching step of etching the tungsten film after the first depositing step;
a second depositing step of depositing a deposited film;
a second etching step of etching the tungsten film by using a mixed gas containing a Cl₂ gas, an N₂ gas, a CF₄ gas and a C₄F₈ gas after the second depositing step; and
a third etching step of etching the tungsten film after the second etching step, wherein
the second depositing step is performed after the first depositing step and the first etching step are repeated a predetermined number of times, and
the second depositing step, the second etching step, and the third etching step are repeated a predetermined number of times.

2. The plasma processing method according to claim 1, wherein
the insulating film is a silicon oxide film.

3. The plasma processing method according to claim 1, wherein
the third etching step is performed by using a mixed gas containing a Cl₂ gas, an N₂ gas, a CF₄ gas and a C₄F₈ gas.

4. The plasma processing method according to claim 3, wherein
the second etching step is performed while radio frequency power is supplied to a sample stage on which a sample having the stacked film is placed, and
the third etching step is performed without supplying radio frequency power to the sample stage.

5. The plasma processing method according to claim 4, wherein
the second depositing step is performed by using a C₄F₈ gas.
